(19) United States
(12) Patent Application Publication
(10) Pub. No.: US 2022/0255030 A1
(43) Pub. Date: Aug. 11, 2022

(54) COLOR CONVERSION SUBSTRATE, MANUFACTURING METHOD THEREOF AND DISPLAY PANEL

(71) Applicant: BOE TECHNOLOGY GROUP CO., LTD., Beijing (CN)

(72) Inventors: Yong YU, Beijing (CN); Shi SHU, Beijing (CN); Chuanxiang XU, Beijing (CN); Xiang LI, Beijing (CN); Haitao HUANG, Beijing (CN); Yang YUE, Beijing (CN); Yujie LIU, Beijing (CN)

(21) Appl. No.: 17/485,304

(22) Filed: Sep. 24, 2021

(30) Foreign Application Priority Data
Feb. 5, 2021 (CN) 202110165980.0

(51) Int. Cl. H01L 51/50; H01L 27/32; H01L 51/52; H01L 51/56

(52) U.S. Cl. CPC H01L 51/502; H01L 27/3246; H01L 27/322; H01L 51/5284; H01L 51/56; H01L 51/5275

(57) ABSTRACT

The present disclosure provides a color conversion substrate and manufacturing method thereof and a display panel. The color conversion substrate includes a base substrate; a color conversion layer on the base substrate and including a bank portion and a plurality of sub-portions having different colors, the bank portion is between adjacent sub-portions to separate the adjacent sub-portions and configured to absorb incident light, and the plurality of sub-portions having different colors are configured to convert the incident light in a same color into light having different colors; an anti-color-interference pattern on a side of the color conversion layer distal to the base substrate, an orthographic projection of the anti-color-interference pattern on the base substrate is within an orthographic projection of the bank portion on the base substrate, the anti-color-interference pattern is configured such that the incident light is refracted and then is transmitted into the bank portion.

### CROSS-REFERENCE TO RELATED APPLICATIONS

The present disclosure claims the priority to Chinese Patent Application No. 202110165980.0, filed on Feb. 5, 2021, the contents of which are incorporated herein by reference in its entirety.

### TECHNICAL FIELD

The present disclosure relates to the field of display technologies, and in particular to a color conversion substrate, a manufacturing method thereof and a display panel.

### BACKGROUND

The OLED (Organic Light-Emitting Diode) products have higher and higher shares in display products, and will still be developed in an accelerated manner in the future. At present, in general large-size OLED products realize color display through a superimposed structure of white OLEDs and a color film. With the technology update and development, people put forward higher color gamut requirements on the display. However, the superimposed structure of the white OLEDs and the color film has a greater bottleneck on the color gamut, and the color gamut is generally less than 90% of the color gamut standard NTSC.

With the vigorous development of display technology, the high color gamut has become an important development direction. The high color gamut means that the displayed pictures become more colorful and have stronger color expressiveness. Quantum Dot (QD) Display Technology belongs to an innovational semiconductor nanocrystal technique. The Quantum Dot (QD) Display Technology can accurately transmit light, effectively improve the color gamut value and viewing angle of the display screen, make the color more pure and bright, and improve the color expressiveness. The display employing the technology not only can generate dynamic colors with a wider color gamut range, but also can display real swatches in the image quality, which goes beyond the traditional backlight technology.

### SUMMARY

As an aspect, a color conversion substrate is provided. The color conversion substrate includes: a base substrate; a color conversion layer on the base substrate and including a bank portion and a plurality of sub-portions in different colors, wherein the bank portion is between adjacent sub-portions of the plurality of sub-portions to separate the adjacent sub-portions, made of an opaque material, and configured to absorb incident light, and the plurality of sub-portions are configured to convert the incident light in a same color into light in different colors; and an anti-color-interference pattern on a side of the color conversion layer distal to the base substrate, wherein an orthographic projection of the anti-color-interference pattern on the base substrate is within an orthographic projection of the bank portion on the base substrate, the anti-color-interference pattern is made of a transparent material and configured such that the incident light is refracted and then is transmitted into the bank portion.

In an embodiment, the color conversion substrate further includes a filler layer on a side of the anti-color-interference pattern distal to the base substrate. A thickness of the anti-color-interference pattern is less than or equal to a thickness of the filler layer, and a refractive index of the anti-color-interference pattern is larger than a refractive index of the filler layer.

In an embodiment, the anti-color-interference pattern is in direct contact with the bank portion of the color conversion layer, and the filler layer is in direct contact with the plurality of sub-portions in different colors of the color conversion layer.

In an embodiment, the thickness of the anti-color-interference pattern is in a range from 4 μm to 10 μm, and the thickness of the filler layer is in a range from 8 μm to 10 μm.

In an embodiment, a center of the orthographic projection of the anti-color-interference pattern on the base substrate is at the same positon as a center of the orthographic projection of the bank portion on the base substrate.

In an embodiment, the anti-color-interference pattern has a thickness of 5 μm. A difference between a size of the orthographic projection of the bank portion on the base substrate along a first direction and a size of the orthographic projection of the anti-color-interference pattern on the base substrate along the first direction is in a range from 4 μm to 6 μm, the first direction being any one direction in a plane where the two orthographic projections are located.

In an embodiment, the refractive index of the filler layer is in a range from 1 to 1.5, and the refractive index of the anti-color-interference pattern is greater than or equal to 1.7.

In an embodiment, the anti-color-interference pattern includes a first film layer made of an organic resin material added with an inorganic material, the inorganic material includes one or more of SiO₂, TIO₂ and ZrO₂, and the organic resin material includes one of acrylic resin and epoxy resin.

In an embodiment, the anti-color-interference pattern further includes a second film layer on a side of the first film layer proximal to the bank portion, and a refractive index of the second film layer is greater than a refractive index of the first film layer.

In an embodiment, an area of an orthographic projection of the second film layer on the base substrate is larger than an area of an orthographic projection of the first film layer on the base substrate and smaller than an area of the orthographic projection of the bank portion on the base substrate.

In an embodiment, the second film layer includes silicon nitride.

In an embodiment, the filler layer includes transparent resin or air, and the bank portion includes a black or gray organic material.

In an embodiment, the color conversion substrate further includes a color resist layer on a side of the color conversion layer proximal to the base substrate. The color resist layer includes a black matrix and a plurality of color resist blocks in different colors, the black matrix is between two adjacent color resist blocks of the plurality of color resist blocks to separate the two adjacent color resist blocks and configured to absorb the incident light, the plurality of color resist blocks in different colors are configured to filter the incident light to obtain monochromatic lights in different colors, and the sub-portions and the color resist blocks having the same color are in one-to-one correspondence with each other, and the bank portion corresponds to the black matrix.

In an embodiment, an orthographic projection of each of the plurality of sub-portions on the base substrate is within an orthographic projection of a corresponding color resist block of the plurality of color resist blocks on the base substrate, and an area of the orthographic projection of each of the plurality of sub-portions on the base substrate is smaller than an area of the orthographic projection of the corresponding color resist block of the plurality of color resist blocks on the base substrate, and an orthographic projection of the black matrix on the base substrate is within the orthographic projection of the bank portion on the base substrate, and an area of the orthographic projection of the bank portion on the base substrate is larger than an area of the orthographic projection of the black matrix on the base substrate.

In an embodiment, the color conversion layer includes a quantum dot material or a fluorescent material.

In an embodiment, the incident light is blue light. The plurality of sub-portions in different colors include a red quantum dot conversion film, a green quantum dot conversion film, and a scattering particle film. The red quantum dot conversion film is configured to convert the blue incident light into red light, the green quantum dot conversion film is configured to convert the blue incident light into green light, and the scattering particle film is configured to scatter and transmit the blue incident light.

As another aspect, a color conversion substrate is provided. The color conversion substrate includes: a base substrate; a color conversion layer on the base substrate and including a plurality of sub-portions in different colors and a bank portion, wherein the bank portion is between adjacent sub-portions of the plurality of sub-portions to separate the adjacent sub-portions, made of an opaque material, and configured to absorb incident light, and the plurality of sub-portions are configured to convert the incident light in a same color into light in different colors; an anti-color-interference pattern on a side of the color conversion layer distal to the base substrate, wherein an orthographic projection of the anti-color-interference pattern on the base substrate is within an orthographic projection of the bank portion on the base substrate, the anti-color-interference pattern is made of a transparent material; and a filler layer on a side of the anti-color-interference pattern distal to the base substrate. A thickness of the anti-color-interference pattern is less than or equal to a thickness of the filler layer, a refractive index of the anti-color-interference pattern is larger than a refractive index of the filler layer, the anti-color-interference pattern is in direct contact with the bank portion of the color conversion layer, and the filler layer is in direct contact with the plurality of sub-portions in different colors of the color conversion layer.

As another aspect, a display panel is provided. The display panel includes a display substrate; and the above color conversion substrate, wherein the display substrate and the color conversion substrate are aligned and assembled to form the display panel.

In an embodiment, the display substrate further includes a filler layer, and the anti-color-interference pattern of the color conversion substrate has a refractive index greater than a refractive index of the filler layer.

As yet another aspect, a method for manufacturing a color conversion substrate is provided. The method includes: forming, on a base substrate, a color conversion layer including a bank portion and a plurality of sub-portions in different colors, such that the bank portion is between adjacent sub-portions of the plurality of sub-portions, wherein the bank portion is made of an opaque material and configured to absorb incident light, and the plurality of sub-portions in different colors are configured to convert the incident light in a same color into light in different colors, respectively; and forming, with a transparent material, an anti-color-interference pattern on a side of the color conversion layer distal to the base substrate, so that an orthographic projection of the anti-color-interference pattern on the base substrate is within an orthographic projection of the bank portion on the base substrate, wherein the anti-color-interference pattern is configured such that the incident light is refracted and then is transmitted into the bank portion.

### BRIEF DESCRIPTION OF THE DRAWINGS

FIG. 1 is a schematic diagram showing a principle of a cross-color interference phenomenon occurring in an OLED display device employing a quantum dot color conversion film;

FIG. 2 is a schematic diagram showing a spectrum for only a green color picture displayed by an OLED display device employing a quantum dot color conversion film;

FIG. 3 is a schematic diagram showing a spectrum for only a red color picture displayed by an OLED display device employing a quantum dot color conversion film;

FIG. 4 is a schematic cross-sectional view showing a structure of a color conversion substrate according to an embodiment of the present disclosure;

FIG. 5 is a schematic cross-sectional view showing a structure of another color conversion substrate according to an embodiment of the present disclosure;

FIG. 6 is a schematic diagram showing wide-angle light irradiation ranges of an OLED display device employing the color conversion substrate in FIG. 5 with and without an anti-color-interference (or anti-cross-color) pattern;

FIG. 7 is a schematic diagram showing a distribution of light intensity of a light-emitting unit vs a light-emitting angle according to an embodiment of the present disclosure;

FIG. 8 is a schematic diagram showing refraction of a large-angle light when the anti-color-interference pattern extends to a region where a sub-portion is located;

FIG. 9 is a schematic cross-sectional view showing a structure obtained after a color conversion substrate and a display substrate are aligned with each other and assembled into a cell according to an embodiment of the present disclosure; and

FIG. 10 is a schematic cross-sectional view showing a structure of another color conversion substrate according to an embodiment of the present disclosure.

### DETAILED DESCRIPTION

In order to make one of ordinary skill in the art better understand the technical solutions of the present disclosure, a color conversion substrate, a manufacturing method thereof and a display panel according to the present disclosure will be further described in detail below with reference to the accompanying drawings and specific embodiments.

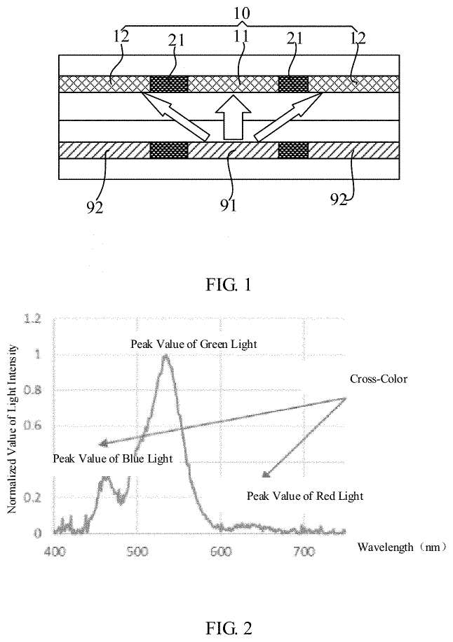

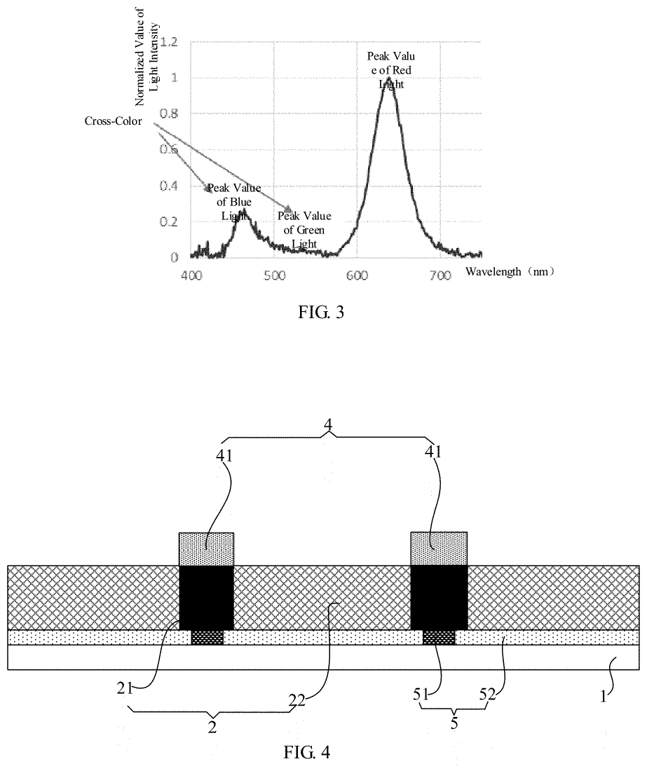

At present, the cross-color phenomenon exists in the OLED display device employing the quantum dot color conversion material technology. FIG. 1 is a schematic diagram showing a principle of a cross-color phenomenon occurring in an OLED display device employing a quantum dot color conversion film. As shown in FIG. 1, the OLED display device includes a plurality of OLED light-emitting units 91 and 92 and a quantum dot color conversion film 10. The quantum dot color conversion film 10 includes a plurality of quantum dot color conversion patterns 11 and 12 and bank portions (i.e., block patterns) 21 disposed between any adjacent two ones of the plurality of quantum dot color conversion patterns 11 and 12. The quantum dot color conversion patterns 11 and 12 are in one-to-one correspondence with the OLED light-emitting units 91 and 92 respectively to realize the conversion of wavelengths corresponding to various colors. When a monochrome picture is displayed, the blue light emitted in a large angle from an OLED light-emitting unit 91 reaches a quantum dot color conversion pattern 12 corresponding to an OLED light-emitting unit 92 adjacent to the OLED light-emitting unit 91. Although the OLED light-emitting unit 92 adjacent to the OLED light-emitting unit 91 does not emit light, light is emitted from the quantum dot color conversion pattern 12 corresponding to the OLED light-emitting unit 92 adjacent to the OLED light-emitting unit 91, and a color of the quantum dot color conversion pattern 11 corresponding to the OLED light-emitting unit 91 is different from a color of the quantum dot color conversion pattern 12 corresponding to the adjacent OLED light-emitting unit 92, therefore a cross-color phenomenon occurs. FIG. 2 is a schematic diagram showing a spectrum for only a green picture displayed by an OLED display device employing a quantum dot color conversion film. When the green picture is only displayed, the spectrum shows that the blue light and red light still have certain brightness. FIG. 3 is a schematic diagram showing a spectrum for only a red picture displayed by an OLED display device employing a quantum dot color conversion film. When the red picture is only displayed, the spectrum shows that the blue light and green light still have certain brightness. The cross-color phenomenon may cause the actual color gamut of the display device to be greatly decreased in the actual display. For example, the color gamut is decreased from 100% of the color gamut standard to 70% of the color gamut standard, namely, the color gamut is decreased by more than 30%, thereby seriously influencing the performance of the products.

At present, the OLED display device employing the quantum dot color conversion material technology includes an OLED display substrate and a quantum dot color conversion substrate which are aligned with each other and assembled into a cell. The OLED display substrate includes a driving backboard, OLED light-emitting units on the driving backboard, and an encapsulation structure for encapsulating the OLED light-emitting units. The OLED display substrate includes the OLED light-emitting units emitting blue light. The quantum dot color conversion substrate includes a red quantum dot conversion film, a green quantum dot conversion film and a scattering particle film which are arranged on the base substrate, bank portions between adjacent quantum dot conversion films, and a filler layer on a side of the quantum dot conversion film distal to the base substrate. The filler layer is configured to fill a cell gap between the OLED display substrate and the quantum dot color conversion substrate after the OLED display substrate and the quantum dot color conversion substrate are aligned with each other and assembled into a cell. The red quantum dot conversion film, the green quantum dot conversion film and the scattering particle film are in one-to-one correspondence with the OLED light-emitting units. The red quantum dot conversion film may convert blue light emitted by the OLED light-emitting unit into red light, the green quantum dot conversion film may convert the blue light emitted by the OLED light-emitting unit into green light, and the scattering particle film may enable the blue light emitted by the OLED light-emitting unit to be scattered and transmitted, so that the red light, the green light and the blue light are mixed to realize the color display of the OLED display device. On one hand, the bank portion may absorb light emitted in a large angle by the corresponding OLED light-emitting unit, thereby improving that cross-color between adjacent OLED pixels (including the OLED light-emitting unit and the quantum dot conversion film arranged correspondingly); on the other hand, during the manufacturing process, the quantum dot conversion films having different colors may be spaced apart from each other, which is benefit for the formation of the quantum dot conversion film with a large thickness, thereby improving the conversion efficiency of the quantum dot conversion film for blue light.

According to the principle of the cross-color of the OLED display device adopting the quantum dot conversion film, since the OLED light-emitting unit is far away from the corresponding quantum dot conversion film and the bank portion has a constant width, a portion of the light emitted in a large angle by the OLED light-emitting unit may cross over the bank portion and reach the adjacent OLED pixel, therefore the cross-color phenomenon occurs.

The performance of the display device is greatly degraded due to the cross-color in the OLED display device adopting the quantum dot conversion film. The mainstream improvements in the disclosed technology are as follow. Firstly, a width of the bank portion is increased, so that more large-angle light can be shielded by the bank portion and prevented from being irradiated to an adjacent OLED pixel; however, this solution may result in a decrease in an aperture ratio of the OLED display device and result in a decrease in the light outgoing efficiency of the OLED display device. Secondly, a distance between the OLED light-emitting unit and the corresponding quantum dot conversion film is decreased, namely a thickness of a filler layer and a thickness of an encapsulation structure are decreased; according to this solution, the distance between the OLED light-emitting unit and the corresponding quantum dot conversion film needs to be greatly decreased; greatly reducing the thickness of the encapsulation structure may lead to the encapsulation failure of the encapsulation structure for the OLED light-emitting units, and greatly reducing the thickness of the filler layer may lead to a non-uniform cell gap formed after the OLED display substrate and the quantum dot color conversion substrate are aligned with each other and assembled into a cell, resulting in defects such as poor display mura (i.e. the display texture).

In order to solve the problem in related art that the cross-color phenomenon cannot be well improved in the display device employing the quantum dot conversion film, an embodiment of the present disclosure provides a color conversion substrate. As shown in FIG. 4, the color conversion substrate includes: a base substrate 1; a color conversion layer 2 disposed on the base substrate 1, wherein the color conversion layer 2 includes a bank portion 21 and a plurality of sub-portions 22 having different colors, the bank portion 21 is located between adjacent sub-portions of the plurality of sub-portions 22 to separate the adjacent sub-portions and configured to absorb incident light, and the plurality of sub-portions 22 having different colors are configured to respectively convert light with a first wavelength of a same color into the light with a second wavelength of a different color; an anti-color-interference pattern 4 on a side of the color conversion layer 2 distal to the base substrate 1, wherein an orthographic projection of the anti-color-interference pattern 4 on the base substrate 1 is within an orthographic projection of the bank portion 21 on the base substrate 1. A material of the anti-color-interference pattern 4 is a transparent material, and a material of the bank portion 21 is an opaque material.

A material of the color conversion layer 2 is a quantum dot material or a fluorescent material. The principle for converting a color of light by the color conversion layer made of the quantum dot material is the same as the principle for converting a color of light by the color conversion layer made of the fluorescent material, both for converting light with the first wavelength of a certain color (such as blue light) into light with the second wavelength of a different color (such as red or green). The color conversion layer made of quantum dot material and the color conversion layer made of fluorescent material are relatively mature technologies for light color conversion, which will not be repeated here. In an embodiment, a color conversion layer 2 made of the quantum dot material will be described as an example.

In an embodiment, the sub-portions 22 having different colors include a red quantum dot conversion film, a green quantum dot conversion film, and a scattering particle film. The red quantum dot conversion film, the green quantum dot conversion film, and the scattering particle film respectively are in one-to-one correspondence with the light-emitting units emitting light with a first wavelength of a certain color (such as blue light). The red quantum dot conversion film may convert the light with the first wavelength of the certain color emitted by the light-emitting units into red light, the green quantum dot conversion film may convert the light with the first wavelength of the certain color emitted by the light-emitting units into green light, and the scattering particle film may scatter and transmit the light with the first wavelength of the certain color (such as blue light) emitted by the light-emitting units. The color display of display device is realized after the red, green and blue light are mixed. The bank portions 21 are made of a black or gray organic material. On one hand, the bank portions 21 may absorb light irradiated on the bank portions, so that cross-color between adjacent pixels (including a light-emitting unit and a quantum dot conversion film arranged correspondingly) can be improved; on the other hand, the quantum dot conversion films having different colors can be spaced apart from each other during manufacturing, while a thicker quantum dot conversion film is facilitated to be formed, thereby improving the conversion efficiency of the quantum dot conversion film for light with the first wavelength of a certain color.

In the color conversion substrate, the anti-color-interference pattern 4 is located on a side of the color conversion layer 2 distal to the base substrate 1, the orthographic projection of the anti-color-interference pattern 4 on the base substrate 1 is within the orthographic projection of the bank portion 21 on the base substrate 1; the material of the anti-color-interference pattern 4 is a transparent material, and the material of the bank portion 21 is an opaque material. In this way, on one hand, most of light emitted in a large angle by an adjacent light-emitting unit and irradiated on the anti-color-interference pattern 4 is refracted and irradiated on the bank portion 21, and absorbed by the bank portion 21, thereby greatly reducing the quantity of light emitted in a large angle by a light-emitting unit and irradiated on a sub-portion corresponding to a light-emitting unit adjacent to the light-emitting unit, and greatly improving the cross-color phenomenon in the display device employing the color conversion layer 2; the color conversion substrate is provided with the anti-color-interference pattern 4, so that the cross-color phenomenon can be greatly prevented without greatly decreasing the distance between the light-emitting unit and the quantum dot conversion film corresponding to the light-emitting unit, and the defects due to the great reduction of the thickness of the filler layer and the great reduction of the thickness of the encapsulation structure of the light-emitting unit can be avoided. In addition, since the bank portions 21 are located in a non-display region (e.g., a wiring region) between the light-emitting units, the orthographic projection of the anti-color-interference pattern 4 on the base substrate 1 is within the orthographic projection of the bank portion 21 on the base substrate 1, an aperture ratio of the display device employing the color conversion substrate cannot be reduced.

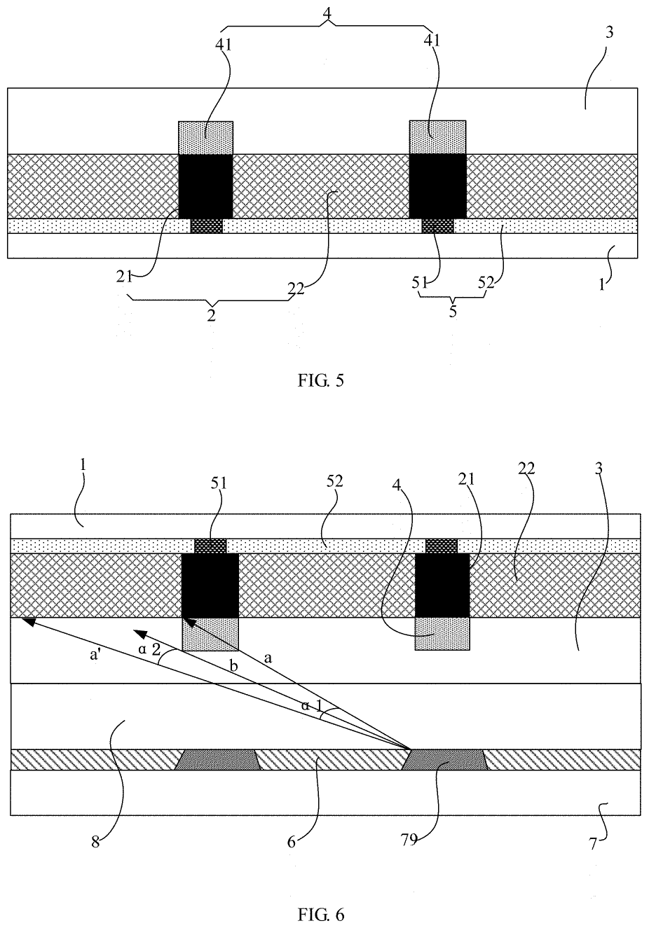

In an embodiment, as shown in FIG. 5, the color conversion substrate further includes a filler layer 3 on a side of the anti-color-interference pattern 4 distal to the base substrate 1. A refractive index of the anti-color-interference pattern 4 is greater than a refractive index of the filler layer 3. On one hand, the filler layer 3 is configured to protect a surface of the color conversion substrate on which the color conversion layer 2 and the anti-color-interference pattern 4 are formed and to planarize a surface of the color conversion substrate to be aligned and assembled with the display substrate, so that the color conversion substrate and the display substrate can be aligned and assembled very well; on the other hand, the filler layer 3 is configured to fill a cell gap between the display substrate which emits light with the first wavelength of a certain color and the color conversion substrate after the display substrate and the color conversion substrate are aligned and assembled to form a cell.

As shown in FIG. 6, the anti-color-interference pattern 4 is in direct contact with the bank portion 21 of the color conversion layer 2, and the filler layer 3 is in direct contact with the plurality of sub-portions 22 having different colors of the color conversion layer 2. That is, no layer is located between the anti-color-interference pattern and the bank portion of the color conversion layer, and no layer is between the filler layer and the plurality of sub-portions having different colors of the color conversion layer, so that a thickness of the color conversion substrate can be decreased, and the risk of cross-color can be lower.

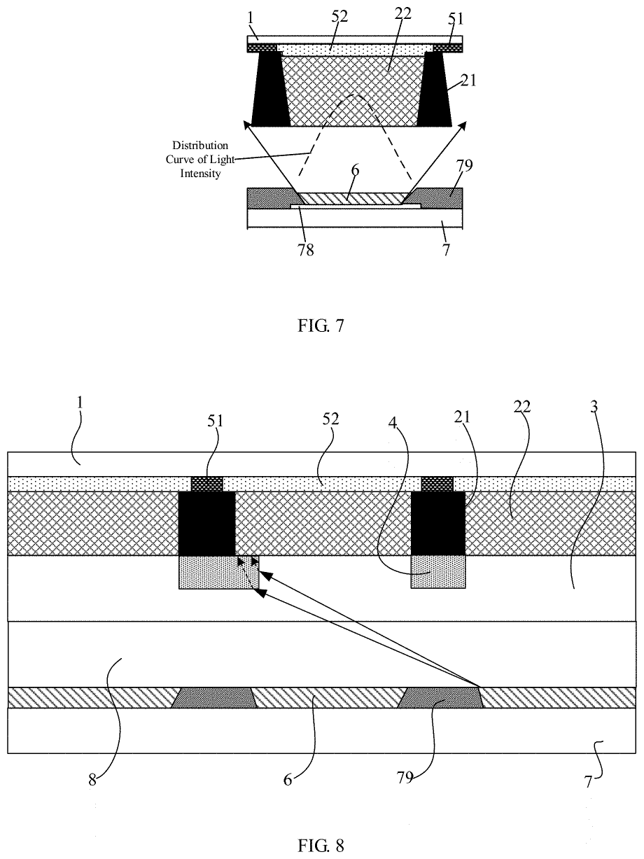

In an embodiment, as shown in FIG. 6, a range α1 between arrow a and arrow a′ represents a range, which is a large range, of large-angle light in a case where the cross-color occurs without the anti-color-interference pattern; and a range α2 between arrow b and arrow a′ represents a range, which is a small range, of a large-angle light in a case where the cross-color occurs with an anti-color-interference pattern 4 disposed. As shown in FIG. 7, according to the distribution of the light-emitting angles of the light-emitting unit 6, the light-emitting intensities are normally distributed with the light-emitting angles. That is to say, the smaller the included angle between the light emitted by the light-emitting unit 6 and a normal direction P is (e.g., light with the light-emitting angle from 0° to 80°, also called small-angle light), the normal direction P being perpendicular to a plane where the light-emitting unit 6 is located, the stronger the light-emitting intensity is; the larger the included angle between the light emitted by the light-emitting unit 6 and the normal direction P is (e.g., light with the light-emitting angle from 80° to 90°, also called large-angle light), the weaker the light-emitting intensity is. Thus, the anti-color-interference pattern 4 is provided, so that the amount of large-angle light that leads to cross-color can be greatly decreased and the cross-color phenomenon can be greatly prevented. Since the anti-color-interference pattern 4 is provided, after the large-angle light in the light-emitting angle from α1 to α2 emitted by the light emitting unit 6 is refracted by the filler layer 3 and the anti-color-interference pattern 4, the propagation direction of the light changes. Since the refractive index of the anti-color-interference pattern 4 is greater than the refractive index of the filler layer 3, an incident angle of the light irradiated to the anti-color-interference pattern 4 from the filler layer 3 is greater than an exit angle of the light, and then the light converges, as shown in FIG. 8, as a result, most of the light irradiated to the anti-color-interference pattern 4 can exit out from a contact surface of the anti-color-interference pattern 4 and the bank portion 21, and most of the light exit from the anti-color-interference pattern 4 can be irradiated to the bank portion 21 and absorbed by the bank portion 21, thereby further preventing the cross-color phenomenon of the light and greatly improving the color gamut of the display device adopting the color conversion substrate. Meanwhile, according to the Fresnel formula, the reflectivity=(n2−n1)²/(n2+n1)², where n2 is the refractive index of the anti-color-interference pattern 4, and n1 is the refractive index of the filler layer 3. The higher the refractive index is, the higher the reflectivity is. As shown in FIG. 8, in a case where the anti-color-interference pattern 4 extends to a region where the sub-portion 22 is located, that is, the anti-color-interference pattern 4 with a high refractive index is formed in an opening region of the display substrate corresponding to the light-emitting unit 6, it will result in an increased reflectivity and decreased transmissivity of a region of the opening region where the anti-color-interference pattern 4 is formed, that is, an decreased amount of light emitted from the light-emitting unit 6 to the sub-portion 22, and a decreased aperture ratio and decreased light efficiency of the display device employing the color conversion substrate; in addition, in a case where the anti-color-interference pattern 4 extends to a region where the sub-portion 22 is located, the cross-color may happen to light from the adjacent pixels, so that the color gamut of the display device employing the color conversion substrate is decreased. Therefore, in the embodiment, the filler layer 3 is formed on a side of the anti-color-interference pattern 4 distal to the base substrate 1, the refractive index of the anti-color-interference pattern 4 is greater than the refractive index of the filler layer 3, and the orthographic projection of the anti-color-interference pattern 4 on the base substrate 1 is within the orthographic projection of the bank portion 21 on the base substrate 1, so that a majority of light emitted in a great angle by an adjacent light-emitting unit 6 and irradiated on the anti-color-interference pattern 4 via the filler layer 3 can be refracted and then irradiated on the bank portion 21, and absorbed by the bank portion 21, so that the amount of light emitted in a great angle by a light-emitting unit 6 and irradiated to the sub-portion 22 corresponding to the adjacent light-emitting unit 6 can be greatly decreased, and the cross-color phenomenon of the display device employing the color conversion layer 2 can be greatly prevented; since the color conversion substrate is provided with the anti-color-interference pattern 4, the cross-color phenomenon can be greatly avoided without greatly decreasing the distance between the light-emitting unit 6 and the quantum dot conversion film corresponding to the light-emitting unit 6, and the defects caused by greatly decreasing the thickness of the filler layer 3 and the thickness of the encapsulation structure of the light-emitting unit 6 can be avoided; in addition, since the bank portion 21 corresponds to the non-display region (e.g., the wiring region) between the light-emitting units 6, the orthographic projection of the anti-color-interference pattern 4 on the base substrate 1 is within the orthographic projection of the bank portion 21 on the base substrate 1, the aperture ratio of the display device employing the color conversion substrate cannot be reduced.

Optionally, the thickness of the anti-color-interference pattern 4 is less than or equal to the thickness of the filler layer 3. The filler layer 3 is generally made of a transparent resin material. The filler layer 3 is formed after the anti-color-interference pattern 4 is formed. The manufacturing process for the filler layer 3 generally includes film coating, exposure, development, curing processes and the like. The filler layer 3 has a certain leveling property after the formation of the film and before curing. If the thickness of the anti-color-interference pattern 4 is too large, the fluidity of the filler layer 3 will be affected, so that a surface of the filler layer 3 cannot achieve a good flat effect after curing. In order to ensure that the color conversion substrate and the display substrate are well aligned and assembled to form a cell, it is required to from a planarization layer for planarizing an out-of-flatness surface of the filler layer 3, which result in a large cell gap and an increased process cost and the like. In addition, if the thickness of the anti-color-interference pattern 4 is greater than the thickness of the filler layer 3, the filler layer 3 will be lift up when the color conversion substrate and the display substrate are aligned and assembled to form a cell, which result in a further increased cell gap. The above-described problem can be avoided if the thickness of the anti-color-interference pattern 4 is smaller than or equal to the thickness of the filler layer 3.

It should be noted that the filler layer 3 may be formed by air.

Optionally, the thickness of the anti-color-interference pattern 4 ranges from 4 μm to 10 μm, and the thickness of the filler layer 3 ranges from 8 μm to 10 μm.

Optionally, an area of the orthographic projection of the anti-color-interference pattern 4 on the base substrate 1 is smaller than or equal to an area of the orthographic projection of the bank portion 21 on the base substrate 1. A center of the orthographic projection of the anti-color-interference pattern 4 on the base substrate 1 coincides with/is at the same position as a center of the orthographic projection of the bank portion 21 on the base substrate 1. With the arrangement, the cross-color phenomenon between adjacent pixels can be better prevented. When a pattern of the orthographic projection, on the base substrate 1, of each of the anti-color-interference pattern 4 and the bank portion 21 has a regular polygon shape, such as a triangle, a rectangle, a regular polygon and the like, a center of an orthographic projection, on the base substrate 1, of each of the anti-color-interference pattern 4 and the bank portion 21 is an intersection where diagonal lines of the pattern of the orthographic projection intersect with each other. When a pattern of an orthographic projection, on the base substrate 1, of each of the anti-color-interference pattern 4 and the bank portion 21 has a circular shape, the center of the orthographic projection is a circle center of the pattern of the orthographic projection. When a pattern of an orthographic projection, on the base substrate 1, of each of the anti-color-interference pattern 4 and the bank portion 21 has an irregular shape, the center of the pattern of the orthographic projection is a gravity center of the pattern of the orthographic projection.

Optionally, the anti-color-interference pattern 4 has a thickness of 5 μm, and a difference between a size of the orthographic projection of the bank portion 21 on the base substrate 1 and a size of the orthographic projection of the anti-color-interference pattern 4 on the base substrate 1 along any direction in a plane where the orthographic projections are located ranges from 4 μm to 6 μm. That is, an area of the orthographic projection of the anti-color-interference pattern 4 on the base substrate 1 is smaller than an area of the orthographic projection of the bank portion 21 on the base substrate 1, so that the cross-color phenomenon between the adjacent pixels can be prevented better.

Optionally, the filler layer 3 has a refractive index which ranges from 1 to 1.5, and the anti-color-interference pattern 4 has a refractive index equal to or greater than 1.7.

In an embodiment, in a case where an orthographic projection, on the base substrate 1, of each of the bank portion 21 and the anti-color-interference pattern 4 along any direction in the plane where the orthographic projections are located has a constant width, the thicker the anti-color-interference 4 is, the greater the color gamut improvement of the display device employing the color conversion substrate is. Table 1 below shows the color gamut and energy utilization rate of the display device adopting the color conversion substrate vs. the thickness of the anti-color-interference patterns 4, when the orthographic projection, on the base substrate 1, of each of the bank portion 21 and the anti-color-interference pattern 4 along any direction in the plane where the orthographic projections are located has a width of 20 μm. As can be seen from the simulation results in Table 1, the thicker the anti-color-interference pattern 4 is, the higher the color gamut of the display device is, while ensuring a higher energy utilization rate.

TABLE 1

| Thickness of anti-color-interference | | |
|---|---|---|
| pattern/μm (Width of | | |
| orthographic projection of | | |
| anti-color-interference | | Energy |
| pattern = Width of orthographic | Color | Utilization |
| projection of bank portion = 20 μm) | Gamut | Rate |
| No anti-color-interference pattern provided | 48.80% | 33.945% |
| 8 | 67.50% | 32.68% |
| 6 | 67.00% | 32.79% |
| 5 | 66.00% | 32.84% |
| 4 | 58.00% | 32.88% |

In a case where the anti-color-interference pattern 4 has a constant thickness, the difference between the size of the orthographic projection, on the base substrate 1, of the bank portion 21 and the size of the orthographic projection, on the base substrate 1, of the anti-color-interference pattern 4 along any direction in the plane where the orthographic projection of the bank portion on the base substrate 1 and the orthographic projection of the anti-color-interference pattern 4 on the base substrate 1 are located may change. According to the theoretical analysis, the width of the orthographic projection of the anti-color-interference pattern 4 on the base substrate 1 cannot be too large, otherwise the light outgoing rate in the opening region of the display substrate is influenced; and the width of the orthographic projection of the anti-color-interference pattern 4 on the base substrate 1 cannot be too small, otherwise the anti-color-interference pattern cannot be formed due to the limitation of the process capability. Table 2 below shows, when the anti-color-interference pattern 4 has a thickness of 5 μm, the color gamut and energy utilization rate of the display device adopting the color conversion substrate vs. the difference between the size of the orthographic projection, on the base substrate 1, of the bank portion 21 and the size of the orthographic projection, on the base substrate 1, of the anti-color-interference pattern 4 along any direction in the plane where the orthographic projection of the bank portion on the base substrate 1 and the orthographic projection of the anti-color-interference pattern 4 on the base substrate 1 are located. As can be seen from the simulation results in Table 2, the wider the orthographic projection of the anti-color-interference pattern 4 on the base substrate 1 is, the lower the color gamut and the energy utilization rate of the display device are. As the width of the orthographic projection of the anti-color-interference pattern 4 on the base substrate 1 decreases, the color gamut and energy utilization rate of the display device increase in an approximately linear manner.

TABLE 2

| Width difference between | | |
|---|---|---|
| orthographic projections of the | | |
| bank portion and the | | |
| anti-color-interference pattern | | Energy |
| along a same direction/μm | Color | Utilization |
| (Thickness = 5 μm) | Gamut | Rate |
| No anti-color-interference pattern provided | 48.80% | 33.945% |
| W_{anti-color-interference pattern} = W_{bank portion} | 66% | 32.84% |
| W_{bank portion} − W_{anti-color-interference pattern} = 5 | 68% | 33.04% |
| W_{bank portion} − W_{anti-color-interference pattern} = 4 | 67.8% | 33.02% |
| W_{bank portion} − W_{anti-color-interference pattern} = 6 | 68.2% | 33.1% |
| W_{anti-color-interference pattern} − W_{bank portion} = 5 | 64% | 32.32% |

Optionally, the anti-color-interference pattern 4 includes a first film layer 41 made of an organic resin material added with inorganic material particles. The inorganic material includes any one or more of SiO₂, TIO₂ and ZrO₂, and the organic resin material includes any one of acrylic resin and epoxy resin. The organic resin material added with the inorganic material particles may be formed through a photolithography process (including film coating, pre-baking, exposure, development and post-baking processes) or an ink-jet printing process during manufacturing. The temperature during the process is lower than a temperature (i.e., 170° C.) during the mainstream process for forming the quantum dot conversion film, so that the formation of the organic resin material cannot influence the quantum dot conversion film while the requirement of the refractive index of the anti-color-interference pattern 4 can be met.

Optionally, as shown in FIG. 4 and FIG. 5, the color conversion substrate further includes a color resist layer 5 on a side of the color conversion layer 2 proximal to the base substrate 1. The color resist layer 5 includes a black matrix 51 and a plurality of color resist blocks 52 having different colors. The black matrix 51 is disposed between any adjacent color resist blocks of the plurality of color resist blocks 52 to separate the adjacent color resist blocks 52 and may absorb incident light. The color resist block 52 with different colors may pass the light with the same color as the color of the color resist block 52 and filter out the light with different colors from the color of the color resist block 52. The sub-portions 22 and the color resist blocks 52 having the same color are in one-to-one correspondence with each other. The position of the bank portion 21 corresponds to the position of the black matrix 51. The black matrix 51 is made of a black organic material, and the black matrix 51 can absorb light irradiated thereon and can also shield a non-display region (e.g., the wiring region) between adjacent light-emitting units 6 on the display substrate. The color resist blocks 52 include a red color resist block, a green color resist block, and a blue color resist block. The red color resist block corresponds to the red quantum dot conversion film, the green color resist block corresponds to the green quantum dot conversion film, and the blue color resist block corresponds to the scattering particle film. The color resist block 52 may filter out the light unconverted by the corresponding quantum dot conversion film, so that the color purity of the display device adopting the color conversion substrate is higher, and the color gamut of the display device can be improved.

Optionally, an orthographic projection of the sub-portion 22 on base substrate 1 is located within an orthographic projection of the color resist block 52 on base substrate 1, and an area of the orthographic projection of the color resist block 52 on base substrate 1 is larger than an area of the orthographic projection of the sub-portion 22 on base substrate 1. An orthographic projection of the black matrix 51 on the base substrate 1 is located within the orthographic projection of the bank portion 21 on the base substrate 1, and an area of the orthographic projection of the bank portion 21 on the base substrate 1 is larger than an area of the orthographic projection of the black matrix 51 on the base substrate 1. With such a configuration, during displaying, the light emitted by the light-emitting unit 6 sequentially passes through the sub-portion 22 and the color resist block 52, and exits out from the base substrate 1. The sub-portion 22 may absorb the light (e.g., the blue light) with a first wavelength and convert the light into the light with a second wavelength (e.g., red light or green light). The area of the orthographic projection of the color resist block 52 on the base substrate 1 is larger than the area of the orthographic projection of the sub-portion 22 on the base substrate 1, so that the light passing through the sub-portions 22 may be irradiated on the corresponding color resist blocks 52, thereby avoiding the light leakage caused by light passing through the sub-portions 22 not irradiated on the corresponding color resistor blocks 52, and avoiding the decrease of the color gamut of the display device employing the color conversion substrate due to the light leakage.

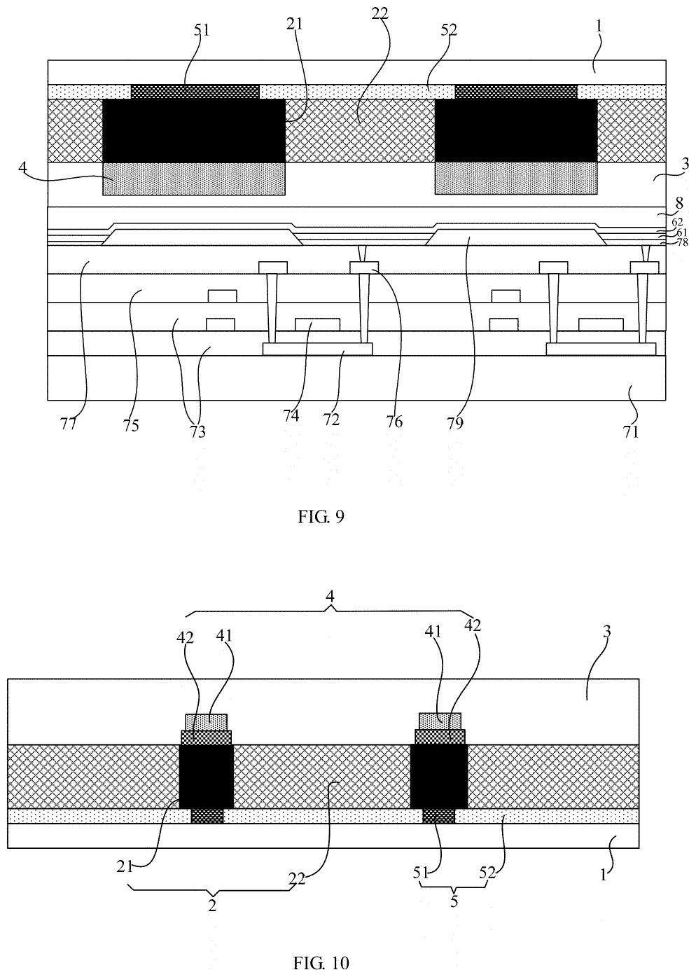

In an embodiment, as shown in FIG. 6 to FIG. 9, the light-emitting unit 6 may be an OLED light-emitting unit. The display substrate includes a driving backplane 7, OLED light-emitting units disposed on the driving backplane 7, and an encapsulation structure 8 for encapsulating the OLED light-emitting units. The driving backplane 7 includes a base substrate 71, and a buffer layer, an active layer 72, a gate insulating layer 73, a gate layer 74, an interlayer insulating layer 75, a source-drain metal layer 76, a planarization layer 77, a pixel electrode layer 78, and a pixel defining layer 79 sequentially disposed on the base substrate 71. The light-emitting unit 6 includes a light-emitting functional layer 61 and a cathode 62. The light-emitting function layer 61 includes a hole injection layer, a hole transport layer, a light-emitting layer, an electron transport layer, and an electron injection layer. The OLED light-emitting unit is a top-emission type blue OLED device. The cathode 62 includes a semi-transparent metal such as Mg or Ag. The encapsulation structure 8 includes three encapsulation layers, i.e., an inorganic layer, an organic layer and an inorganic layer sequentially stacked, wherein the inorganic layer is made of SiN, and the organic layer is made of an organic transparent material.

It should be noted that the light-emitting unit may also be an LED light-emitting unit, a Micro LED light-emitting unit, a Mini LED light-emitting unit, or an LCD (i.e., liquid crystal display) light-emitting unit. When the light-emitting unit is any one of above light-emitting units except for the LCD light-emitting unit, the driving backplane may have the same arrangement as above driving backplane. When the light-emitting unit is an LCD light-emitting unit, the driving circuit in the driving backplane may adopt a mature pixel driving circuit at current. In addition, the display substrate further includes a backlight structure on a side of the driving backplane distal to the color conversion substrate and configured to provide the backlight for the LCD light-emitting unit. The specific operation principle of the LCD display substrate belongs to a mature technology, and will not be described herein again.

Based on the above structure of the color conversion substrate, an embodiment further provides a method for manufacturing the color conversion substrate. The method includes sequentially forming the color conversion layer, the anti-color-interference pattern, and the filler layer on the base substrate.

The color conversion layer and the filler layer may be formed through the traditional processes, and the details will not be repeated herein. The anti-color-interference pattern may be formed through the photolithography process (including the film coating, pre-baking, exposure, development and post-baking processes) or the ink-jet printing process. The temperature during the process is lower than a temperature during the mainstream process (i.e., 170° C.) for forming the quantum dot conversion film, so that the formation of the anti-color-interference pattern cannot influence the quantum dot conversion film, while the requirement of the refractive index of the anti-color-interference pattern can be met.

An embodiment of the present disclosure further provides a color conversion substrate, which is different from the foregoing embodiment in that, as shown in FIG. 10, on the basis of above embodiment, the anti-color-interference pattern 4 in the embodiment further includes a second film layer 42 on a side of the first film layer 41 proximal to the bank portion 21. A refractive index of the second film layer 42 is greater than a refractive index of the first film layer 41.

With the second film layer 42, the light irradiated to the second film layer 42 from the first film layer 41 can be further refracted, and the light is irradiated to the second film layer 42 with a high refractive index from the first film layer 41 with a low refractive index, so that the light can further converge. As a result, most of the light irradiated to the anti-color-interference pattern 4 can exit out from a contact surface of the anti-color-interference pattern 4 and the bank portion 21, and most of the light exit from the anti-color-interference pattern 4 can be irradiated to the bank portion 21 and absorbed by the bank portion 21, thereby further preventing the cross-color phenomenon of the light and greatly improving the color gamut of the display device adopting the color conversion substrate.

In an embodiment, an area of an orthographic projection of the second film layer 42 on the base substrate 1 is larger than an area of an orthographic projection of the first film layer 41 on the base substrate 1 and smaller than an area of the orthographic projection of the bank portion 21 on the base substrate 1. With such an arrangement, most of the light irradiated to the anti-color-interference pattern 4 can exit out from the contact surface of the anti-color-interference pattern 4 and the bank portion 21, and most of the light exit from the anti-color-interference pattern 4 can be irradiated to the bank portion 21 and absorbed by the bank portion 21, thereby further preventing the cross-color phenomenon of the light.

It should be noted that the area of the orthographic projection of the second film layer on the base substrate may also be equal to the area of the orthographic projection of the bank portion on the base substrate.

Optionally, the second film layer 42 includes silicon nitride. The second film layer 42 made of silicon nitride may be formed through a deposition process at the temperature from 80° C. to 100° C., that is, the second film layer 42 may be formed through a low-temperature deposition process; and then a pattern of the second film layer 42 is formed through a dry etching process. The temperature for forming the second film layer 42 is lower than a mainstream process temperature (i.e., 170° C.) for forming the quantum dot conversion film, so that the formation of the second film layer cannot influence the quantum dot conversion film, while the requirement of the refractive index of the anti-color-interference pattern can be met.

Other structures of the color conversion substrate in the embodiment are the same as those in the above embodiments, and will not be described herein again.

Based on the above structure of the color conversion substrate, an embodiment further provides a method for manufacturing the color conversion substrate, which is different from the method for manufacturing the color conversion substrate in the above embodiment in that on the basis of the method for forming the color conversion substrate in the above embodiment, the formation of the anti-color-interference pattern in the present embodiment includes sequentially forming the second film layer and the first film layer on the base substrate formed with the color conversion layer. The formation of the first film layer is the same as that in the above embodiment. The second film layer is formed through a low-temperature (i.e., 80° C. to 100° C.) deposition process, and then a pattern of the second film layer is formed through a dry etching process.

Other processes in the method for manufacturing the color conversion substrate in the embodiment are the same as those in the above embodiment, and will not be described herein again.

According to the color conversion substrate provided by the embodiment of the present disclosure, the anti-color-interference pattern is disposed on a side of the color conversion layer distal to the base substrate, the orthographic projection of the anti-color-interference pattern on the base substrate is positioned within the orthographic projection of the bank portion on the base substrate, the material of the anti-color-interference pattern is a transparent material, and the material of the bank portion is an opaque material. As a result, on one hand, a majority of light emitted in a great angle by an adjacent light-emitting unit 6 and irradiated on the anti-color-interference pattern 4 is refracted, and then irradiated on the bank portion 21, and absorbed by the bank portion 21, so that the amount of large-angle light emitted by a light-emitting unit and irradiated to the sub-portion corresponding to the adjacent light-emitting unit can be greatly decreased, and the cross-color phenomenon of the display device employing the color conversion layer 2 can be greatly prevented; since the color conversion substrate is provided with the anti-color-interference pattern, the cross-color phenomenon can be greatly prevented without greatly decreasing a distance between the light-emitting unit and the quantum dot conversion film corresponding to the light-emitting unit, and the defects caused by greatly decreasing the thickness of the filler layer and the thickness of the encapsulation structure of the light-emitting unit can be avoided; in addition, since the bank portion corresponds to the non-display region (e.g., the wiring region) between the light-emitting units, the orthographic projection of the anti-color-interference pattern on the base substrate is within the orthographic projection of the bank portion on the base substrate, the aperture ratio of the display device employing the color conversion substrate cannot be reduced.

An embodiment of the present disclosure further provides a display panel, which includes a display substrate and a color conversion substrate according to anyone of the embodiments described above, where the display substrate is arranged opposite to the color conversion substrate.

In the embodiment, the display substrate further includes a filler layer, and a refractive index of the anti-color-interference pattern of the color conversion substrate is greater than a refractive index of the filler layer. With the filler layer, the cell gap between the color conversion substrate and the display substrate can be filled. Since the refractive index of the anti-color-interference pattern is greater than the refractive index of the filler layer, an incident angle of the light irradiated to the anti-color-interference pattern from the filler layer is greater than an exit angle of the light, so that the light converges, as a result, most of the light irradiated to the anti-color-interference pattern can exit out from a contact surface of the anti-color-interference pattern and the bank portion in the color conversion substrate, and most of the light exit from the anti-color-interference pattern can be irradiated to the bank portion and absorbed by the bank portion, thereby further preventing the cross-color phenomenon of the light and greatly improving the color gamut of the display device.

The display substrate emits light with a first wavelength of the same color, such as blue light, and the display substrate is opposite to the color conversion substrate in any of the above embodiments. Therefore the color conversion substrate may respectively convert the light with the first wavelength of the same color emitted by the display substrate into light with a second wavelength of a different color, such as red, green and blue light, so that the color display of the display panel can be realized after the light with the second wavelength of different colors are mixed.

Optionally, the display substrate includes any one of an LCD display substrate, an OLED display substrate, an LED display substrate, a Micro LED display substrate, and a Mini LED display substrate. In the embodiment, the display substrate emits blue light.

By adopting the color conversion substrate in any of the embodiments, the color display of the display panel can be realized, the cross-color phenomenon of the display panel can be prevented during the display process, and the color gamut and the light effect of the display panel can be improved.

The display panel provided in the embodiment of the present disclosure may be any product or component having a display function, such as an OLED panel, an OLED television, a Micro LED panel, a Micro LED television, a Mini LED panel, a Mini LED television, an LCD panel, an LCD television, a display, a mobile phone, and a navigator.

It should be understood that the above implementations are merely exemplary embodiments for the purpose of illustrating the principles of the present disclosure, however, the present disclosure is not limited thereto. It will be apparent to one of ordinary skill in the art that various changes and modifications can be made without departing from the spirit and spirit of the present disclosure, which are also to be regarded as the scope of the present disclosure.

What is claimed is:

1. A color conversion substrate comprising:
a base substrate;
a color conversion layer on the base substrate and comprising a bank portion and a plurality of sub-portions having different colors, wherein the bank portion is between adjacent sub-portions of the plurality of sub-portions to separate the adjacent sub-portions, made of an opaque material, and configured to absorb incident light; and the plurality of sub-portions having different colors are configured to convert the incident light in a same color into light having different colors; and
an anti-color-interference pattern on a side of the color conversion layer distal to the base substrate, wherein an orthographic projection of the anti-color-interference pattern on the base substrate is within an orthographic projection of the bank portion on the base substrate; the anti-color-interference pattern is made of a transparent material and configured such that the incident light is refracted and then is transmitted into the bank portion.

2. The color conversion substrate of claim 1, further comprising a filler layer on a side of the anti-color-interference pattern distal to the base substrate, wherein
a thickness of the anti-color-interference pattern is less than or equal to a thickness of the filler layer, and
a refractive index of the anti-color-interference pattern is larger than a refractive index of the filler layer.

3. The color conversion substrate of claim 2, wherein
the anti-color-interference pattern is in direct contact with the bank portion of the color conversion layer, and
the filler layer is in direct contact with the plurality of sub-portions having different colors of the color conversion layer.

4. The color conversion substrate of claim 2, wherein
the thickness of the anti-color-interference pattern is in a range from 4 μm to 10 μm, and
the thickness of the filler layer is in a range from 8 μm to 10 μm.

5. The color conversion substrate of claim 1, wherein
a center of the orthographic projection of the anti-color-interference pattern on the base substrate is at the same positon as a center of the orthographic projection of the bank portion on the base substrate.

6. The color conversion substrate of claim 1, wherein
the anti-color-interference pattern has a thickness of 5 μm,
a difference between a size of the orthographic projection of the bank portion on the base substrate along a first direction and a size of the orthographic projection of the anti-color-interference pattern on the base substrate along the first direction is in a range from 4 μm to 6 μm, the first direction being any one direction in a plane where the two orthographic projections are located.

7. The color conversion substrate of claim 2, wherein
the refractive index of the filler layer is in a range from 1 to 1.5, and
the refractive index of the anti-color-interference pattern is greater than or equal to 1.7.

8. The color conversion substrate of claim 1, wherein the anti-color-interference pattern comprises a first film layer made of an organic resin material added with an inorganic material,
the inorganic material comprises one or more of SiO₂, TIO₂ and ZrO₂, and
the organic resin material comprises one of acrylic resin and epoxy resin.

9. The color conversion substrate of claim 8, wherein
the anti-color-interference pattern further comprises a second film layer on a side of the first film layer proximal to the bank portion, and
a refractive index of the second film layer is greater than a refractive index of the first film layer.

10. The color conversion substrate of claim 9, wherein
an area of an orthographic projection of the second film layer on the base substrate is larger than an area of an orthographic projection of the first film layer on the base substrate and smaller than an area of the orthographic projection of the bank portion on the base substrate.

11. The color conversion substrate of claim 9, wherein
the second film layer comprises silicon nitride.

12. The color conversion substrate of claim 2, wherein
the filler layer comprises transparent resin or air, and
the bank portion comprises a black or gray organic material.

13. The color conversion substrate of claim 1, further comprising a color resist layer on a side of the color conversion layer proximal to the base substrate, wherein
the color resist layer comprises a black matrix and a plurality of color resist blocks having different colors,
the black matrix is between two adjacent color resist blocks of the plurality of color resist blocks to separate the two adjacent color resist blocks and configured to absorb the incident light,
the plurality of color resist blocks having different colors are configured to filter the incident light to obtain monochromatic light having different colors, and
the sub-portions and the color resist blocks having the same color are in one-to-one correspondence with each other, and the bank portion corresponds to the black matrix.

14. The color conversion substrate of claim 13, wherein
an orthographic projection of each of the plurality of sub-portions on the base substrate is within an orthographic projection of a corresponding color resist block of the plurality of color resist blocks on the base substrate, and an area of the orthographic projection of each of the plurality of sub-portions on the base substrate is smaller than an area of the orthographic projection of the corresponding color resist block of the plurality of color resist blocks on the base substrate, and
an orthographic projection of the black matrix on the base substrate is within the orthographic projection of the bank portion on the base substrate, and an area of the orthographic projection of the bank portion on the base substrate is larger than an area of the orthographic projection of the black matrix on the base substrate.

15. The color conversion substrate of claim 1, wherein the color conversion layer comprises a quantum dot material or a fluorescent material.

16. The color conversion substrate of claim 15, wherein
the incident light is blue light,
the plurality of sub-portions having different colors comprise a red quantum dot conversion film, a green quantum dot conversion film, and a scattering particle film,
the red quantum dot conversion film is configured to convert the blue incident light into red light,
the green quantum dot conversion film is configured to convert the blue incident light into green light, and
the scattering particle film is configured to scatter and transmit the blue incident light.

17. A color conversion substrate comprising:
a base substrate;
a color conversion layer on the base substrate and comprising a plurality of sub-portions having different colors and a bank portion, wherein the bank portion is between adjacent sub-portions of the plurality of sub-portions to separate the adjacent sub-portions, made of an opaque material, and configured to absorb incident light; and the plurality of sub-portions having different colors are configured to convert the incident light in a same color into light having different colors;
an anti-color-interference pattern on a side of the color conversion layer distal to the base substrate, wherein an orthographic projection of the anti-color-interference pattern on the base substrate is within an orthographic projection of the bank portion on the base substrate, the anti-color-interference pattern is made of a transparent material; and
a filler layer on a side of the anti-color-interference pattern distal to the base substrate, wherein
a thickness of the anti-color-interference pattern is less than or equal to a thickness of the filler layer,
a refractive index of the anti-color-interference pattern is larger than a refractive index of the filler layer,
the anti-color-interference pattern is in direct contact with the bank portion of the color conversion layer, and
the filler layer is in direct contact with the plurality of sub-portions having different colors of the color conversion layer.

18. A display panel, comprising:
a display substrate; and
the color conversion substrate of claim 1, wherein the display substrate and the color conversion substrate are aligned and assembled to form the display panel.

19. The display panel of claim 18, wherein the display substrate further comprises a filler layer, and the anti-color-interference pattern of the color conversion substrate has a refractive index greater than a refractive index of the filler layer.

20. A method for manufacturing a color conversion substrate, comprising:
forming, on a base substrate, a color conversion layer comprising a bank portion and a plurality of sub-portions having different colors, such that the bank portion is between adjacent sub-portions of plurality of sub-portions, wherein the bank portion is made of an opaque material and configured to absorb incident light; and the plurality of sub-portions having different colors are configured to convert the incident light in a same color into light having different colors, respectively; and
forming, with a transparent material, an anti-color-interference pattern on a side of the color conversion layer distal to the base substrate, so that an orthographic projection of the anti-color-interference pattern on the base substrate is within an orthographic projection of the bank portion on the base substrate, wherein the anti-color-interference pattern is configured such that the incident light is refracted and then is transmitted into the bank portion.
